(19) United States
(12) Patent Application Publication
(10) Pub. No.: US 2023/0302599 A1
(43) Pub. Date: Sep. 28, 2023

(54) GRINDING METHOD OF WAFER

(71) Applicant: DISCO CORPORATION, Tokyo (JP)

(72) Inventors: Tatsuya SUZUKI, Tokyo (JP); Kohei TSUJIMOTO, Tokyo (JP)

(21) Appl. No.: 18/186,323

(22) Filed: Mar. 20, 2023

(30) Foreign Application Priority Data
Mar. 28, 2022 (JP) 2022-051346

(51) Int. Cl. B24B 7/22

(52) U.S. Cl. CPC B24B 7/228

(57) ABSTRACT

A second relative speed of a grinding wheel and a wafer along a second direction in a grinding step is set such that a relative movement of the grinding wheel and the wafer along a first direction and a relative movement of the grinding wheel and the wafer along the second direction are concurrently initiated and are concurrently finished. Specifically, this second relative speed is set taking into consideration parameters which are optionally set, and an expected wear thickness of multiple grinding stones as known before or in a course of the grinding step, in other words, the absolute value of an expected variation in thickness of the grinding stones through the grinding step.

### BACKGROUND OF THE INVENTION

### Field of the Invention

The present invention relates to a grinding method of a wafer with multiple devices formed on a side of a front surface thereof, for forming a recessed portion of a predetermined depth by grinding the wafer on a side of a back surface thereof.

### Description of the Related Art

Chips of devices such as integrated circuits (ICs) are essential elements in various kinds of electronic equipment such as mobile phones and personal computers. These chips are manufactured, for example, by dividing a wafer, on the side of a front surface of which multiple devices are formed, into respective regions including the individual devices.

This wafer may be thinned before its division for miniaturization of manufactured chips. Examples of a method for thinning a wafer include, for example, grinding with a grinding wheel that has multiple grinding stones and a wheel base having an arrangement surface on which the grinding stones are fixed at intervals in an annular pattern. This grinding is generally performed in the following order.

A wafer is first held with a back surface thereof kept exposed. While both the grinding wheel, which has an outer diameter greater than a radius of the wafer, and the wafer are being rotated, any one of the grinding stones and a center of a back surface of the wafer are then brought into contact with each other. With both the grinding wheel and the wafer kept rotating, the arrangement surface of the wheel base and a front surface of the wafer are next brought closer to each other along a direction in which an axis of rotation of the grinding wheel extends (hereinafter also called the “first direction”).

As a consequence, the wafer is ground on the side of the back surface thereof, and is hence thinned. However, this thinning of the wafer leads to a reduction in its rigidity, raising a potential problem that may make difficult the handling of the wafer in subsequent steps. A proposal has therefore been made for a method that grinds a wafer in such a way as thinning the wafer at only a portion thereof where the wafer overlaps multiple devices (see, for example, Japanese Patent Laid-open No. 2007-19461).

In this method, the wafer, as mentioned above, is ground on the side of the back surface thereof using a grinding wheel having an outer diameter shorter than the radius of the wafer, whereby a disk-shaped recessed portion is formed in the back surface of the wafer with an outer peripheral portion of the wafer allowed to remain. This suppresses a reduction in rigidity of the wafer, and hence facilitates the handling of the wafer in subsequent steps.

On the side of the back surface of the wafer ground as described above, a redistribution layer may be formed by photolithography for connection with the devices formed on the side of the front surface. Here, it is to be noted that, if the above-mentioned recessed portion is formed in the back surface of the wafer, a right angle is formed between a bottom surface and a side surface of the recessed portion.

In this case, at the time of draining from the recessed portion a chemical solution used in the photolithography to dissolve a resist, a portion of the chemical solution may remain in vicinities of an outer periphery of the bottom surface of the recessed portion. Taking this potential problem into consideration, a proposal has been made for a method that grinds a wafer so as to form a recessed portion of an inverted truncated conical shape in a back surface of the wafer (see, for example, Japanese Patent Laid-open No. 2011-54808).

In this method, the wafer is ground on the side of its back surface by, with both a grinding wheel and the wafer kept rotating, bringing an arrangement surface of a wheel base and a front surface of the wafer closer to each other along the first direction, and also bringing an axis of rotation of the grinding wheel and a center of the wafer closer to each other along a direction perpendicular to the first direction (hereinafter also called the “second direction”).

In this case, an obtuse angle is formed between a bottom surface and a side surface of a recessed portion formed in the back surface of the wafer. This facilitates draining the above described chemical solution from the recessed portion even if a redistribution layer is formed by photolithography on the side of the back surface of the wafer.

### SUMMARY OF THE INVENTION

When a wafer is ground using a grinding wheel, its grinding stones are worn, so that their thickness decreases. If a recessed portion of an inverted truncated conical shape is formed in a back surface of the wafer by grinding the wafer on the side of its back surface without taking the wear of the grinding stones into consideration, the recessed portion has a depth shallower than a predetermined depth.

In such a case, the wafer, after the recessed portion of the inverted truncated conical shape has been formed in the back surface of the wafer, may be further ground on the side of its back surface by moving both the grinding wheel and the wafer relative to each other along the first direction, with both the grinding wheel and the wafer kept rotating, until the depth of the recessed portion reaches the predetermined depth.

If the recessed portion of the predetermined depth is formed in the back surface of the wafer by such procedures, however, a right angle is formed between a bottom surface and a lower peripheral edge of a side surface of the recessed portion. In this case, when draining the above-mentioned chemical solution or the like from the recessed portion, a portion of the chemical solution or the like may remain in vicinities of an outer periphery of the bottom surface of the recessed portion.

With the foregoing problem in view, the present invention has as an object thereof the provision of a grinding method of a wafer, which can form a recessed portion, the recessed portion having a predetermined depth and having an obtuse angle between its bottom surface and side surface, in a back surface of the wafer even if multiple grinding stones wear in association with grinding of the wafer on the side of its back surface.

In accordance with an aspect of the present invention, there is provided a grinding method of a wafer with multiple devices formed on a side of a front surface thereof, for forming a recessed portion of a predetermined depth by grinding the wafer on a side of a back surface thereof. The grinding method includes a holding step of holding the wafer with the back surface kept exposed, a contacting step of bringing any one of the multiple grinding stones, the grinding stones being fixed at intervals in an annular pattern on an arrangement surface of a wheel base of a grinding wheel, and a center of the back surface of the wafer into contact with each other while both the grinding wheel and the wafer are being rotated, and a grinding step of, after the contacting step, grinding the wafer on the side of the back surface thereof by, with both the grinding wheel and the wafer kept rotating, bringing the arrangement surface of the wheel base and the front surface of the wafer closer to each other by a first movement distance along a first direction, and also bringing an axis of rotation of the grinding wheel and a center of the wafer closer to each other by a second movement distance along a second direction perpendicular to the first direction. The first movement distance is a distance obtained by adding the predetermined depth and an expected wear thickness of the grinding stones when the wafer is ground to the predetermined depth. The second movement distance is a distance optionally set to be shorter than a width along the second direction of each of the grinding stones. In the grinding step, the grinding wheel and the wafer are moved relative to each other at a first relative speed along the first direction, and the first relative speed is an optionally set constant speed. In the grinding step, the grinding wheel and the wafer are moved relative to each other at a second relative speed along the second direction, and the second relative speed is a constant or variable speed set, taking the predetermined depth, the expected wear thickness, the second movement distance, and the first relative speed into consideration such that the relative movement of the grinding wheel and the wafer along the first direction and the relative movement of the grinding wheel and the wafer along the second direction are concurrently initiated and are concurrently finished.

Preferably, the expected wear thickness is known before the grinding step, and the second relative speed is a speed obtained by dividing the second movement distance with a time obtained by dividing the first movement distance with the first relative speed.

As an alternative, the recessed portion includes a first portion of an inverted truncated conical shape and a second portion of another inverted truncated conical shape having a side surface with a sharper inclination than a side surface of the first portion. The grinding step includes a pre-grinding step of forming the first portion on the side of the back surface of the wafer by, with both the grinding wheel and the wafer kept rotating, bringing the arrangement surface of the wheel base and the front surface of the wafer closer to each other by a third movement distance along the first direction, and also bringing the axis of rotation of the grinding wheel and the center of the wafer closer to each other by a fourth movement distance along the second direction, a measurement step of, after the pre-grinding step, measuring a depth of the first portion, and a main grinding step of forming the second portion on the side of the back surface of the wafer by, with both the grinding wheel and the wafer kept rotating, bringing the arrangement surface of the wheel base and the front surface of the wafer closer to each other by a fifth movement distance along the first direction, and also bringing the axis of rotation of the grinding wheel and the center of the wafer closer to each other by a sixth movement distance along the second direction. The second relative speed in the pre-grinding step is a speed obtained by dividing the second movement distance with a time obtained by dividing the predetermined depth with the first relative speed. The third movement distance is a distance optionally set to be shorter than the predetermined depth. The fourth movement distance is a distance obtained by multiplying the second relative speed in the pre-grinding step and a time obtained by dividing the third movement distance with the first relative speed. The expected wear distance is a distance obtained by multiplying the predetermined depth and a value obtained by dividing, with the depth of the first portion, a distance obtained by subtracting the depth of the first portion from the third movement distance. The fifth movement distance is a distance obtained by adding a distance, which is obtained by subtracting the third movement distance from the predetermined depth, and the expected wear thickness. The sixth movement distance is a distance obtained by subtracting the fourth movement distance from the second movement distance. The second relative speed in the main grinding step is a speed obtained by dividing the sixth movement distance with a time obtained by dividing the fifth movement distance with the first relative speed.

In the present invention, the second relative speed of the grinding wheel and the wafer along the second direction in the grinding step is set such that the relative movement of the grinding wheel and the wafer along the first direction and the relative movement of the grinding wheel and the wafer along the second direction are concurrently initiated and are concurrently finished.

Specifically, this second relative speed is set taking into consideration parameters which are optionally set, and the expected wear thickness of the grinding stones as known before or in a course of the grinding step, in other words, the absolute value of an expected variation in thickness of the grinding stones through the grinding step. In the present invention, this can form, in the back surface of the wafer, a recessed portion having a predetermined depth and having an obtuse angle between its bottom surface and side surface.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating an example of a grinding machine for practicing the present invention;

FIG. 2 is a cross-sectional view schematically illustrating the grinding machine;

FIG. 3 is a flow chart schematically illustrating a grinding method according to an embodiment of the present invention for a wafer;

FIG. 4A is a side view, partly in cross-section, schematically illustrating a positional relation between multiple grinding stones and the wafer in a first stage of a contacting step of the grinding method of FIG. 3;

FIG. 4B is a side view, partly in cross-section, schematically illustrating a positional relation between the multiple grinding stones and the wafer in a second stage of the contacting step of the grinding method of FIG. 3;

FIG. 5A is a side view, partly in cross-section, schematically illustrating one example (in which an expected wear thickness of the grinding stones is known) of the grinding step of the grinding method of FIG. 3;

FIG. 5B is a cross-sectional view schematically illustrating the wafer obtained after the grinding step illustrated in FIG. 5A;

FIG. 6 is a flow chart schematically illustrating individual steps included in another example (in which the expected wear thickness of the grinding stones is not known) of the grinding step of the grinding method of FIG. 3;

FIG. 7A is a side view, partly in cross-section, schematically illustrating how a pre-grinding step is performed in the grinding step of FIG. 6;

FIG. 7B is a cross-sectional view schematically illustrating a wafer obtained after the pre-grinding step of FIG. 7A;

FIG. 8A is a side view, partly in cross-section, schematically illustrating how a main grinding step is performed in the grinding step of FIG. 6; and

FIG. 8B is a cross-sectional view schematically illustrating a wafer obtained after the main grinding step of FIG. 8A.

### DETAILED DESCRIPTION OF THE PREFERRED EMBODIMENT

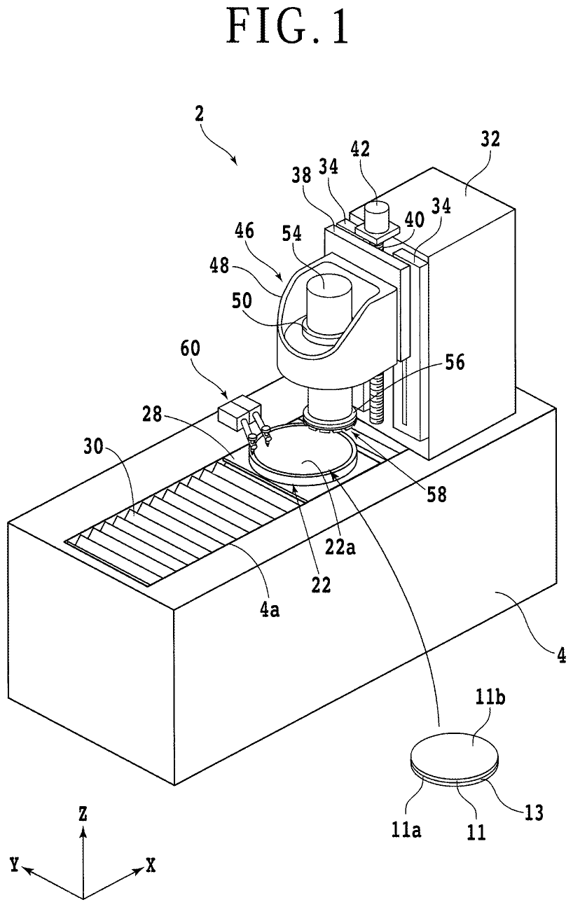

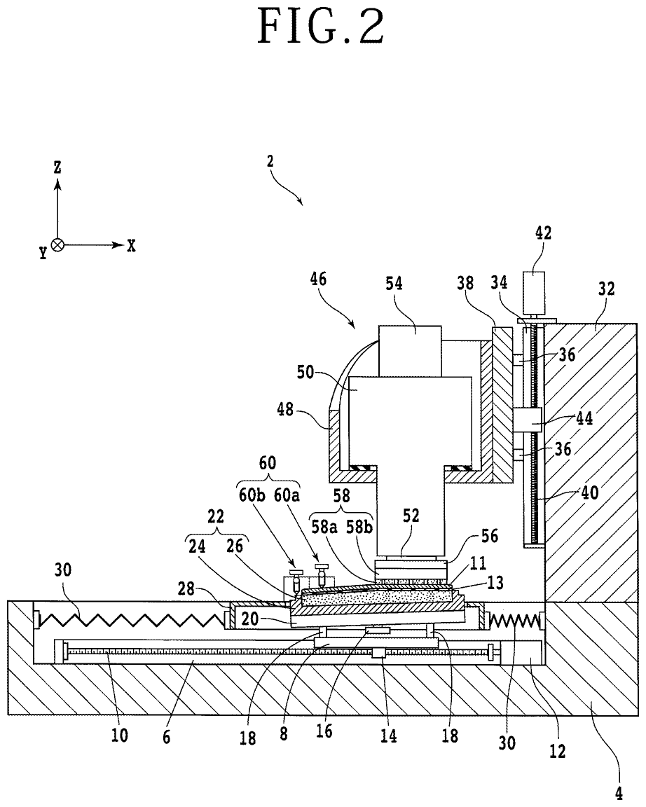

With reference to the attached drawings, a description will be made in detail about an embodiment of the present invention. FIG. 1 is a perspective view schematically illustrating an example of a grinding machine for practicing the present invention, and FIG. 2 is a cross-sectional view schematically illustrating the grinding machine. It is to be noted that an X-axis direction (front-rear direction) and a Y-axis direction (left-right direction) indicated in FIGS. 1 and 2 are directions orthogonal to each other on a horizontal plane, and that a Z-axis direction (top-down direction) is a direction (vertical direction) orthogonal to the X-axis direction and Y-axis direction.

A grinding machine 2 illustrated in FIGS. 1 and 2 has a bed 4 that supports individual elements. On an upper surface of the bed 4, a parallelepipedal cavity 4a is formed extending along the X-axis direction. On a bottom surface of the cavity 4a, a pair of guide rails 6 are disposed, each, extending along the X-axis direction (see FIG. 2). To upper sides of the paired guide rails 6, a parallelepipedal X-axis moving plate 8 is attached in such a fashion that it is slidable along the X-axis direction.

Between the paired guide rails 6, a threaded shaft 10 is arranged extending along the X-axis direction. To a rear end portion of the threaded shaft 10, a pulse motor 12 is connected to rotate the threaded shaft 10. On a threaded outer peripheral surface of the threaded shaft 10, a nut 14 with a number of balls accommodated therein such that they circulate according to rotation of the threaded shaft 10 is disposed, so that a ball screw is constructed.

The nut 14 is fixed to a side of a lower surface of the X-axis moving plate 8. The X-axis moving plate 8 therefore moves together with the nut 14 along the X-axis direction when the threaded shaft 10 is rotated by the pulse motor 12. On the X-axis moving plate 8, a rotary member, to a lower end portion of which a driven pulley 16 is connected, and a drive source (not illustrated) such as a motor connected to a driving pulley (not illustrated) are disposed.

An endless belt (not illustrated) is wrapped around the driven pulley 16 and the driving pulley. On the X-axis moving plate 8, a tilt adjustment mechanism is disposed. The tilt adjustment mechanism has one fixed leg (not illustrated), and two adjustable legs 18 that are each adjustable in length along the Z-axis direction. The fixed leg and two adjustable legs 18 are connected to a side of a lower surface of a table base 20, and support the table base 20.

A through-hole (not illustrated) is centrally formed in the table base 20. Inserted in the through-hole is the rotary member to the lower end portion of which the driven pulley 16 is connected. The rotary member is connected at an upper end portion thereof to a side of a lower surface of a disk-shaped chuck table 22. When the rotary drive source connected to the driving pulley is operated to rotate the endless belt wrapped around the driven pulley 16, the chuck table 22 rotates along a peripheral direction thereof.

The chuck table 22 is supported on the table base 20 via bearings (not illustrated). The table base 20 therefore does not rotate when the chuck table 22 is rotated as mentioned above. On the other hand, not only the table base 20 but also the chuck table 22 is adjusted in tilt when the two adjustable legs 18 are adjusted in length along the Z-axis direction in the tilt adjustment mechanism.

The chuck table 22 has a disk-shaped frame body 24 made from ceramics or the like. The frame body 24 has a disk-shaped bottom wall, and a cylindrical side wall disposed upright from the bottom wall. Accordingly, a disk-shaped recess defined by the bottom wall and the side wall is formed on a side of an upper surface of the frame body 24.

The side wall of the frame body 24 has an inner diameter slightly shorter than a diameter of a wafer 11 to be mentioned subsequently herein, and an outer diameter slightly longer than the diameter of the wafer 11. Through the bottom wall of the frame body 24, a flow channel (not illustrated) is formed opening in a bottom surface of the recessed portion, and this flow channel is in communication with a suction source (not illustrated) such as an ejector.

In the recessed portion formed on the side of the upper surface of the frame body 24, a disk-shaped porous plate 26 that has a diameter substantially equal to a diameter of the recessed portion is fixed. The porous plate 26 is made, for example, from porous ceramics. An upper surface of the porous plate 26 and an upper surface of the side wall of the frame body 24 have, in combination, a shape corresponding to the side surface of a cone (a shape upwardly protruding more at its center than at its outer periphery).

When the suction source that is in communication with the flow channel formed inside the frame body 24 is operated, a suction force acts on a space in a vicinity of the upper surface of the porous plate 26. The upper surface of the porous plate 26 and the upper surface of the side wall of the frame body 24 therefore function as a holding surface 22a of the chuck table 22 (see FIG. 1).

By operating the suction source, for example, with the wafer 11 placed on the holding surface 22a of the chuck table 22 such that a back surface 11b of the wafer 11, to a front surface 11a of which a protective tape 13 is bonded, is directed upward, the wafer 11 is held by suction on the chuck table 22.

The wafer 11 is made, for example, from a semiconductor material such as silicon, and multiple devices are formed on a side of its front surface 11a. On the other hand, the protective tape 13 is made, for example, from resin, and prevents damage to the devices when grinding the wafer 11 on the side of the back surface 11b.

Around the chuck table 22, a parallelepipedal table cover 28 is disposed surrounding the chuck table 22 such that the holding surface 22a is exposed. The table cover 28 has a width (a length along the Y-axis direction) substantially equal to a width of the cavity 4a formed in the upper surface of the bed 4. In front and rear of the table cover 28, dust- and splash-proof covers 30 that are expandable and contractible along the X-axis direction are disposed, respectively.

In a region of the upper surface of the bed 4, the region being located in rear of the cavity 4a, a quadrangular prism-shaped support structure 32 is disposed. On a front surface of the support structure 32, a pair of guide rails 34 are disposed, each, extending along the Z-axis direction. To a front side of each of the paired guide rails 34, sliders 36 are disposed in such a fashion that they are slidable along the Z-axis direction (see FIG. 2).

The sliders 36 are fixed at front end portions thereof to a side of a rear surface of a parallelepipedal Z-axis moving plate 38. Between the paired guide rails 34, a threaded shaft 40 is arranged extending along the Z-axis direction. To an upper end portion of the threaded shaft 40, a pulse motor 42 is connected to rotate the threaded shaft 40.

On a threaded outer peripheral surface of the threaded shaft 40, a nut 44 with a number of balls accommodated therein such that they circulate according to rotation of the threaded shaft 40 is disposed, so that a ball screw is constructed. The nut 44 is fixed to the side of the rear surface of the Z-axis moving plate 38. The Z-axis moving plate 38 therefore moves together with the nut 44 along the Z-axis direction when the threaded shaft 40 is rotated by the pulse motor 42.

On a front side of the Z-axis moving plate 38, a grinding unit 46 is disposed. The grinding unit 46 has a cylindrical holding member 48 fixed on a front surface of the Z-axis moving plate 38. Inside the holding member 48, a cylindrical spindle housing 50 is disposed extending along the Z-axis direction.

Inside the spindle housing 50, a cylindrical spindle 52 is also disposed extending along the Z-axis direction (see FIG. 2). The spindle 52 is supported in a rotatable fashion on the spindle housing 50, and is connected at an upper end portion thereof to a rotary drive source 54 such as a motor.

On the other hand, the spindle 52 is exposed at a lower end portion thereof from the spindle housing 50, and the lower end portion is fixed to a disk-shaped wheel mount 56. On a side of a lower surface of the wheel mount 56, an annular grinding wheel 58 that has an outer diameter substantially equal to a diameter of the wheel mount 56 is mounted using fixing members (not illustrated) such as bolts.

The grinding wheel 58 has multiple grinding stones 58a, and a wheel base 58b having an arrangement surface on which the grinding stones are fixed at intervals in an annular pattern. When the rotary drive source 54 is operated, the wheel mount 56 and the grinding wheel 58 rotate together with the spindle 52 using, as an axis of rotation, a straight line that extends along the Z-axis direction. At this time, the grinding stones 58a draw an annular trajectory. This trajectory has an outer diameter smaller than a radius of the wafer 11.

The grinding stones 58a contain abrasive grits of diamond, cubic boron nitride (cBN), or the like dispersed in a binder such as a vitrified bond or a resin bond. The wheel base 58b is made, for example, from a metal material such as stainless steel or aluminum.

In another region of the upper surface of the bed 4, this region being located beside the cavity 4a and adjacent the grinding unit 46, a measurement unit 60 is disposed. The measurement unit 60 has a pair of height gauges 60a and 60b, for example, of a type that measure the heights of positions to which their probes come into contact, respectively.

The probe of the height gauge 60a can be arranged such that it comes into contact with the back surface 11b of the wafer 11 held on the chuck table 22 via the protective tape 13. On the other hand, the probe of the height gauge 60b can be arranged such that it comes into contact with the holding surface 22a of the chuck table 22 (specifically, the upper surface of the side wall of the frame body 24).

The sum of a thickness of the wafer 11 and a thickness of the protective tape 13 can therefore be measured at the measurement unit 60 before or during grinding of the wafer 11 on the side of the back surface 11b by arranging the probes of the respective height gauges 60a and 60b as described above.

Owing to the arrangement of the probes of the respective height gauges 60a and 60b as described above, a ground thickness of the wafer 11 (a variation in the thickness of the wafer 11) can be also measured at the measurement unit 60 before or after the grinding of the wafer 11 on the side of the back surface 11b thereof.

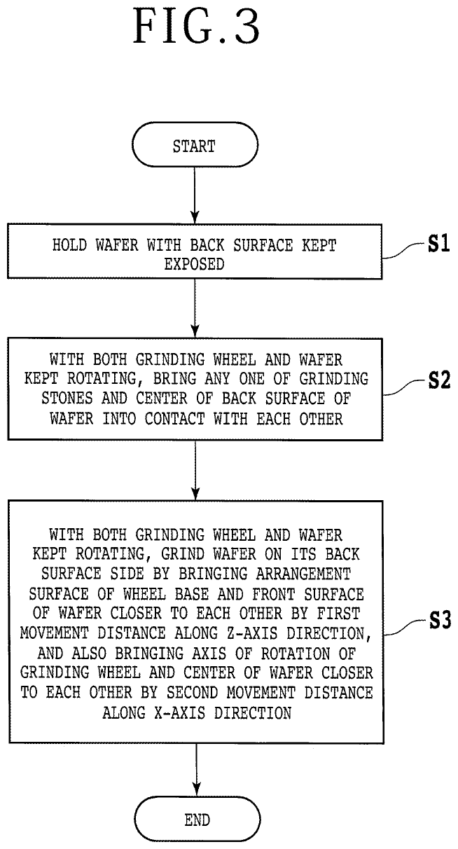

FIG. 3 is a flow chart schematically illustrating a grinding method according to an embodiment of the present invention for the wafer, which forms a recessed portion of a predetermined depth by grinding the wafer 11 on the side of the back surface 11b thereof on the grinding machine 2.

In this method, the wafer 11 is first held with the back surface 11b kept exposed (holding step: S1). In this holding step (S1), the chuck table 22 is first moved frontward. Specifically, the chuck table 22 is moved such that it is positioned at a location where it is apart from the grinding unit 46 and the wafer 11 can be transferred onto its holding surface 22a.

The wafer 11 is next transferred onto the holding surface 22a of the chuck table 22 with the protective tape 13 interposed between the wafer 11 and the holding surface 22a such that a center of the wafer 11 and a center of the holding surface 22a of the chuck table 22 overlap. The suction source, which is in communication with the porous plate 26 via the flow channel formed in the frame body 24 of the chuck table 22, is then operated such that the wafer 11 is held by suction on the chuck table 22. The holding step (S1) is now completed.

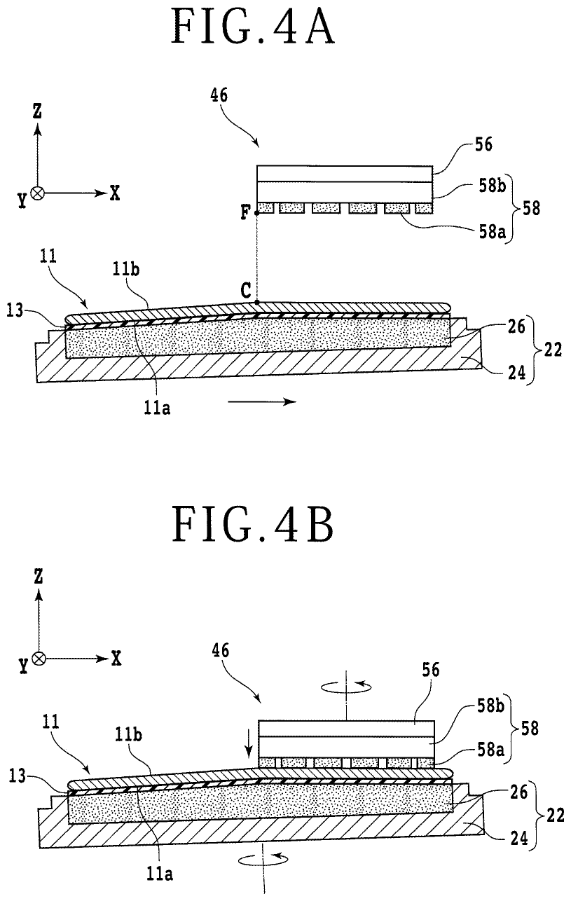

With both the grinding wheel 58 and the wafer 11 kept rotating, any one of the grinding stones 58a and a center of the back surface 11b of the wafer 11 are brought into contact with each other (contacting step: S2). FIGS. 4A and 4B are side views, partly in cross-section, schematically illustrating positional relations between the grinding stones 58a and the wafer 11 in a first stage and a second stage of the contacting step (S2), respectively.

In the first stage of this contacting step (S2), the chuck table 22 is first moved rearward. Specifically, the chuck table 22 is moved such that, as seen in plan, a front end F of the trajectory of the grinding stones 58a when the grinding wheel 58 is rotated and a center C of the back surface 11b of the wafer 11 overlap in the Z-axis direction (see FIG. 4A).

It is to be noted that the tilt of the chuck table 22 may be adjusted as needed before or after moving the chuck table 22 rearward. Specifically, the tilt of the chuck table 22 may be adjusted such that an extension line, which extends rearward from the center of the holding surface 22a of the chuck table 22, lies in parallel with the X-axis direction.

In the second stage of the contacting step (S2), both the grinding wheel 58 and the chuck table 22 are next rotated. With the grinding wheel 58 and the chuck table 22 kept rotating, the grinding unit 46 is then lowered until lower surfaces of the grinding stones 58a come into contact with the back surface 11b of the wafer 11 (see FIG. 4B). The contacting step (S2) is now completed.

With both the grinding wheel 58 and the wafer 11 kept rotating, the arrangement surface of the wheel base 58b and the front surface 11a of the wafer 11 are next brought closer to each other by a first movement distance along the Z-axis direction, and the axis of rotation of the grinding wheel 58 and the center of the wafer 11 are also brought closer to each other by a second movement distance along the X-axis direction, whereby the wafer 11 is ground on the side of the back surface 11b (grinding step: S3).

Here, the first movement distance is a distance obtained by adding the depth (predetermined depth) of a recessed portion to be formed in the back surface 11b of the wafer 11 and a thickness to be worn (hereinafter called the “expected wear thickness”) of the grinding stones 58a when the wafer 11 is ground to the predetermined depth. On the other hand, the second movement distance is a distance optionally set to be shorter than a width along a radial direction of the grinding wheel 58 of each of the grinding stones 58a.

Further, the relative speed (hereinafter called the “first relative speed”) of the grinding wheel 58 and the wafer 11 along the Z-axis direction when the wafer 11 is ground generally has substantial effects on the process quality for the wafer 11. In the grinding step (S3), the first relative speed is therefore set at a constant speed suited for the grinding of the wafer 11.

With respect to the relative speed (hereinafter called the “second relative speed”) of the grinding wheel 58 and the wafer 11 along the X-axis direction in the grinding step (S3), on the other hand, its setting method is different depending on whether or not the expected wear thickness of the grinding stones 58a is known before the grinding step (S3).

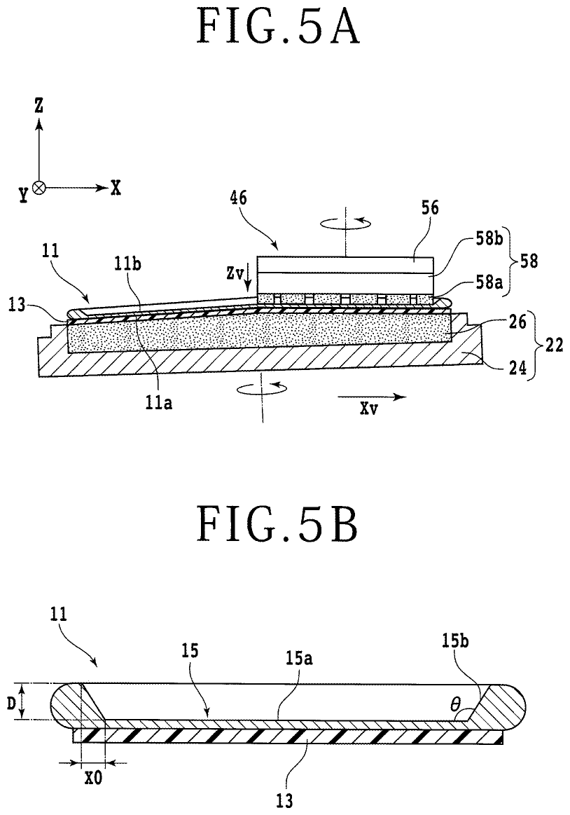

A description will hereinafter be made about a setting method of the second relative speed when the expected wear thickness of the grinding stones 58a is known before the grinding step (S3). FIG. 5A is a side view, partly in cross-section, schematically illustrating the grinding step (S3) in which the second relative speed is set according to this method, and FIG. 5B is a cross-sectional view schematically illustrating the wafer 11 after the grinding step (S3) illustrated in FIG. 5A.

In this case, the second relative speed is set to become equal to a speed obtained by dividing the second movement distance with a time obtained by dividing the first movement distance (the distance obtained by adding the depth of the recessed portion to be formed in the back surface 11b of the wafer 11 and the expected wear thickness of the grinding stones 58a) with the first relative speed.

Therefore, the second relative speed Xv is expressed by the following mathematical formula (1) where D denotes the depth of the recessed portion to be formed in the back surface 11b of the wafer 11, W denotes the expected wear thickness of the grinding stones 58a, X0 demotes the second movement distance, and Zv denotes the first relative speed (see FIGS. 5A and 5B).

$$[ Math . 1 ]$$

$$X v = \frac{X 0}{( D + W ) / Zv} \qquad ( 1 )$$

If the relative movement of the grinding wheel 58 and the wafer 11 along the Z-axis direction and the relative movement of the grinding wheel 58 and the wafer 11 along the X-axis direction are concurrently initiated with the second relative speed set as described above, these movements finish concurrently. In the above-mentioned method, a recessed portion 15 of an inverted truncated conical shape, which has a predetermined depth D and has an obtuse angle as an angle θ formed between a bottom surface 15a and a side surface 15b, is hence formed in the back surface 11b of the wafer 11.

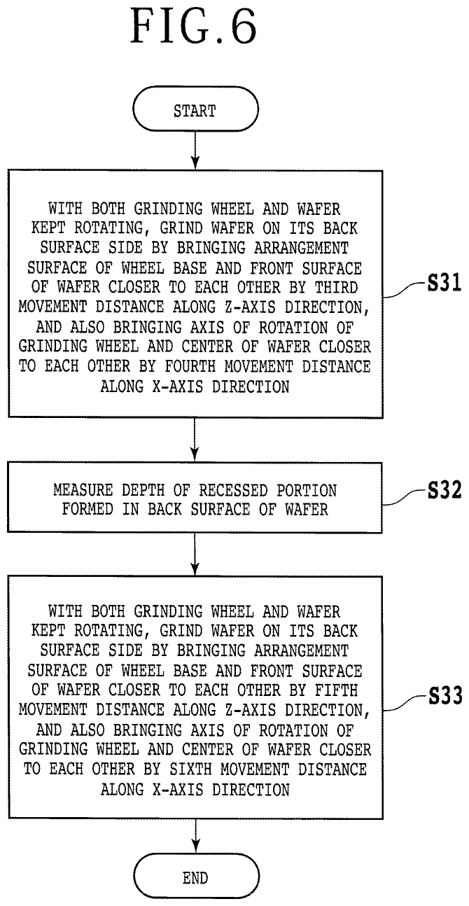

A description will hereinafter be made about a setting method of the second relative speed when the expected wear thickness of the grinding stones 58a is not known before the grinding step (S3). FIG. 6 is a flow chart schematically illustrating individual steps included in the grinding step (S3) in which the second relative speed is set according to this method.

In short, in this grinding step (S3), after the wafer 11 has been ground a little on the side of the back surface 11b, an expected wear thickness of the grinding stones 58a is calculated taking into consideration the depth of a recessed portion formed in the back surface 11b of the wafer 11 by the grinding. In this grinding step (S3), a second relative speed is then set again taking into consideration the expected wear thickness so calculated, followed by formation of a further recessed portion to the desired depth in the back surface 11b of the wafer 11.

Specifically, in this grinding step (S3), with both the grinding wheel 58 and the wafer 11 kept rotating, the arrangement surface of the wheel base 58b and the front surface 11a of the wafer 11 are first brought closer to each other by a third movement distance along the Z-axis direction, and the axis of rotation of the grinding wheel 58 and the center of the wafer 11 are also brought closer to each other by a fourth movement distance along the X-axis direction, whereby the wafer 11 is ground on the side of the back surface 11b (pre-grinding step: S31).

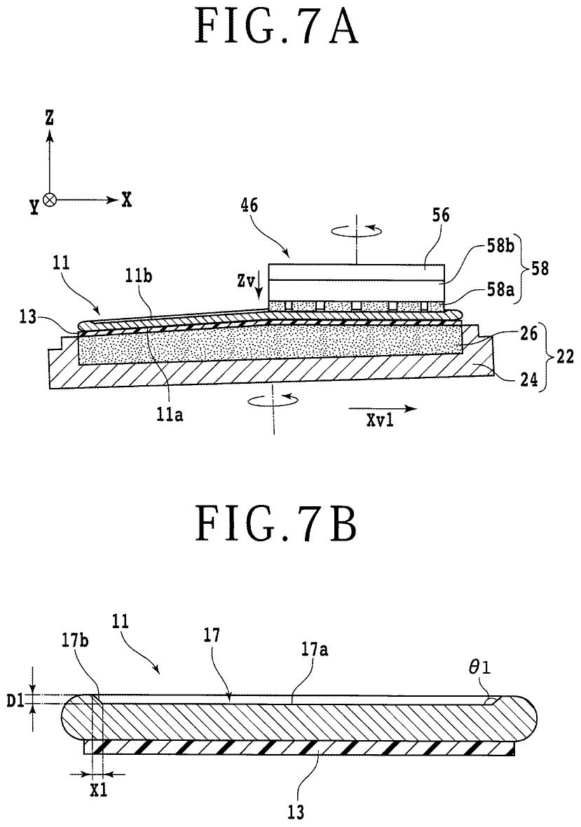

FIG. 7A is a side view, partly in cross-section, schematically illustrating how the pre-grinding step (S31) is performed, and FIG. 7B is a cross-sectional view schematically illustrating the wafer 11 after the pre-grinding step (S31).

In this pre-grinding step (S31), a second relative speed is set to become equal to a speed obtained by dividing the second movement distance X0 with a time obtained by dividing the predetermined depth D with the first relative speed Zv. The second relative speed Xv1 in the pre-grinding step (S31) is therefore expressed by the following mathematical formula (2).

$$[ Math . 2 ]$$

$$X v 1 = \frac{X 0}{D / Zv} = \frac{X0 \times Zv}{D} \qquad ( 2 )$$

Further, the third movement distance is a distance optionally set to be shorter than the depth (the predetermined distance D) of the recessed portion to be formed in the back surface 11b of the wafer 11. Furthermore, the fourth movement distance is a distance obtained by multiplying the second relative speed Xv1 in the pre-grinding step (S31) and a time obtained by dividing the third movement distance with the first relative speed Zv.

The fourth movement distance X1 is therefore expressed by the following mathematical formula (3) where Z1 denotes the third movement distance.

$$[ Math . 3 ]$$

$$X 1 = Xv 1 \times \frac{Z 1}{Z v} = \frac{X 0 \times Z v}{D} \times \frac{Z 1}{Z v} = \frac{X 0}{D} \times Z 1 \qquad ( 3 )$$

If the relative movement of the grinding wheel 58 and the wafer 11 along the Z-axis direction and the relative movement of the grinding wheel 58 and the wafer 11 along the X-axis direction are concurrently initiated with the second relative speed set as described above, these movements finish concurrently. In the pre-grinding step (S31), a recessed portion (first portion) 17 of an inverted truncated conical shape, which has an obtuse angle as an angle θ1 formed between a bottom surface 17a and a side surface 17b, is hence formed in the back surface 11b of the wafer 11 (see FIGS. 7A and 7B).

Preferably, the pre-grinding step (S31) may be performed in a state where the sum of the thickness of the wafer 11 and the thickness of the protective tape 13 is measured by the measurement unit 60 (see FIGS. 1 and 2). Specifically, the pre-grinding step (S31) may be performed with the probe of the height gauge 60a in contact with the back surface 11b of the wafer 11 and the probe of the height gauge 60b in contact with the holding surface 22a of the chuck table 22 (specifically, the upper surface of the side wall of the frame body 24).

The depth of the recessed portion 17 (the depth of the first portion) formed in the back surface 11b of the wafer 11 is next measured (measurement step: S32). Specifically, the depth of the recessed portion 17 is a distance obtained by subtracting the above described sum measured at the measurement unit 60 after the pre-grinding step (S31) from the above described sum measured at the measurement unit 60 before the pre-grinding step (S31).

The measurement of the depth of the recessed portion 17 allows calculation of the expected wear thickness W of the grinding stones 58a when the wafer 11 has been ground to the predetermined depth D. Specifically, this expected wear thickness W is a distance obtained by multiplying the predetermined depth D and a value obtained by dividing a distance, which is obtained by subtracting the depth of the recessed portion 17 from the third movement distance Z1, with the depth of the recessed portion 17.

The expected wear thickness W is therefore expressed by the following mathematical formula (4) where D1 denotes the depth of the recessed portion 17.

$$[ Math . 4 ]$$

$$W = D \times \frac{( Z 1 - D 1 )}{D 1} = \frac{D \times Z 1 - D \times D 1}{D 1} \qquad ( 4 )$$

The measurement step (S32) is performed, for example, after raising the grinding unit 46 such that the grinding wheel 58 and the wafer 11 are apart from each other. As an alternative, the measurement step (S32) may be performed shortly after the pre-grinding step (S31) without raising the grinding unit 46. Further, the measurement step (S32) may be performed with both the grinding wheel 58 and the wafer 11 kept rotating or with both the grinding wheel 58 and the wafer 11 kept out of rotation.

If the grinding wheel 58 and the wafer 11 are apart in the measurement step (S32), the grinding unit 46 is lowered, before a main grinding step (S33) to be mentioned subsequently herein, until the lower surfaces of the grinding stones 58a again come into contact with the back surface 11b of the wafer 11. Similarly, the grinding wheel 58 and the wafer 11 are both rotated again before the main grinding step (S33) to be mentioned subsequently herein if the rotation of both of them is stopped in the measurement step (S32).

With both the grinding wheel 58 and the wafer 11 kept rotating, the arrangement surface of the wheel base 58b and the front surface 11a of the wafer 11 are next brought closer to each other by a fifth movement distance along the Z-axis direction, and the axis of rotation of the grinding wheel 58 and the center of the wafer 11 are also brought closer to each other by a sixth movement distance along the X-axis direction, whereby the wafer 11 is ground on the side of the back surface 11b (main grinding step: S33).

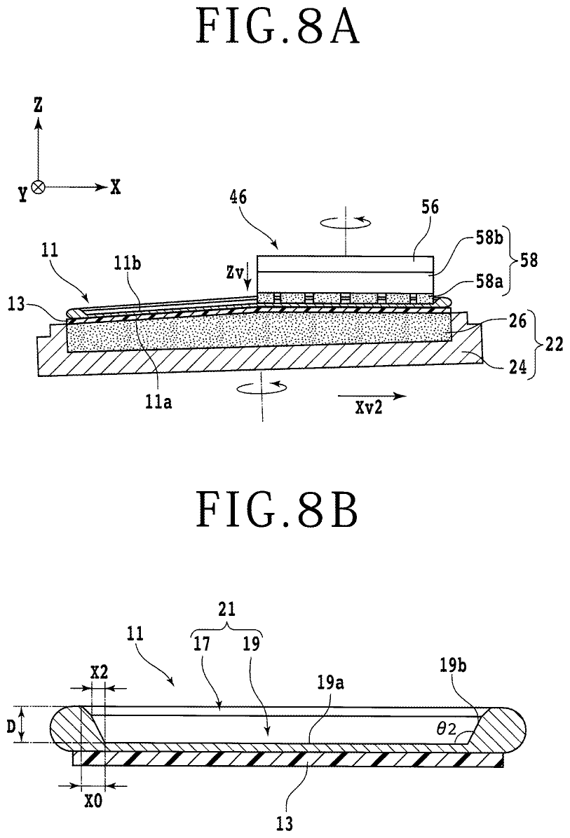

FIG. 8A is a side view, partly in cross-section, schematically illustrating how the main grinding step (S33) is performed, and FIG. 8B is a cross-sectional view schematically illustrating the wafer 11 after the main grinding step (S33).

Here, the fifth movement distance is a distance obtained by adding a distance obtained by subtracting the third movement distance Z1 from the depth (the predetermined depth D) of the recessed portion to be formed in the back surface 11b of the wafer 11 and the expected wear thickness W of the grinding stones 58a when the wafer 11 is ground to the predetermined depth D. The fifth movement distance Z2 is therefore expressed by the following mathematical formula (5).

$$[ Math . 5 ]$$

$$Z 2 = ( D - Z 1 ) + W = ( D - Z 1 ) + \frac{D \times Z 1 - D \times D 1}{D 1} = \frac{D \times D 1 - Z 1 \times D 1 + D \times Z 1 - D \times D 1}{D 1} = ( D - D 1 ) \times \frac{Z 1}{D 1} \qquad ( 5 )$$

Further, the sixth movement distance is a distance obtained by subtracting the fourth movement distance X1 from the second movement distance X0. The sixth movement distance X2 is therefore expressed by the following mathematical formula (6).

$$[ Math . 6 ]$$

$$X Z = X 0 - X 1 = X 0 - ( \frac{X 0}{D} \times Z 1 ) = X 0 \times \frac{( D - Z 1 )}{D} \qquad ( 6 )$$

Moreover, a second relative speed in the main grinding step (S33) is a speed obtained by dividing the sixth movement distance X2 with a time obtained by dividing the fifth movement distance Z2 with the first relative speed Zv. The second relative speed Xv2 in the main grinding step (S33) is therefore expressed by the following mathematical formula (7).

$$[ Math . 7 ]$$

$$Xv 2 = \frac{X 2}{Z 2 / Zv} = \frac{X 0 \times ( D - Z 1 )}{D} \times \frac{D 1}{( D - D 1 ) \times Z 1} \times Zv = \frac{D 1 \times ( D - Z 1 )}{Z 1 \times ( D - D 1 )} \times \frac{X 0 \times Zv}{D} = \frac{D 1 \times ( D - Z 1 )}{Z 1 \times ( D - D 1 )} \times Xv 1 = α \times Xv 1 \qquad ( 7 )$$

If the relative movement of the grinding wheel 58 and the wafer 11 along the Z-axis direction and the relative movement of the grinding wheel 58 and the wafer 11 along the X-axis direction are concurrently initiated with the second relative speed set as described above, these movements finish concurrently. In the main grinding step (S33), a recessed portion (second portion) 19 of a different inverted truncated conical shape, which has an obtuse angle as an angle θ2 formed between a bottom surface 19a and a side surface 19b, is hence formed in the back surface 11b of the wafer 11 (see FIGS. 8A and 8B).

By the foregoing grinding, a recessed portion 21 that includes the recessed portion (first portion) 17 of the inverted truncated conical shape and the recessed portion (second portion) 19 of the different inverted truncated conical shape and has the predetermined depth D is formed in the back surface 11b of the wafer 11. Further, the angle θ2 formed between the bottom surface 19a and the side surface 19b of the second portion 19 is smaller than the angle θ1 formed between the bottom surface 17a and the side surface 17b of the first portion 17. A description will hereinafter be made in detail about this point.

First, as the third movement distance Z1 is a distance longer than the depth D1 of the first portion 17 (Z1>D1), the distance obtained by subtracting the third movement distance Z1 from the predetermined depth D is shorter than a distance obtained by subtracting the depth D1 of the first portion 17 from the predetermined depth D (D−Z1<D−D1). In this case, the product of the third movement distance Z1 and the distance obtained by subtracting the depth D1 of the recessed portion (first portion) 17 from the predetermined depth D is greater than the product of the depth D1 of the first portion 17 and the distance obtained by subtracting the third movement distance Z1 from the predetermined depth D (Z1×(D−D1)>D1×(D−Z1)).

The value a contained in the above described mathematical formula (7) is hence smaller than 1, so that the second relative speed Xv2 in the main grinding step (S33) is slower than the second relative speed Xv2 in the pre-grinding step (S31). As the first relative speed Zv is common to the pre-grinding step (S31) and the main grinding step (S33), the side surface 19b of the second portion 19 has a sharper inclination than the side surface 17b of the first portion 17. As a result, the angle θ2 is smaller than the angle θ1.

In the above-mentioned grinding method, the second relative speed of the grinding wheel 58 and the wafer 11 along the X-axis direction in the grinding step (S3) is set such that the relative movement of the grinding wheel 58 and the wafer 11 along the Z-axis direction and the relative movement of the grinding wheel 58 and the wafer 11 along the X-axis direction are concurrently initiated and are concurrently finished.

Specifically, this second relative speed is set taking into consideration parameters which are optionally set, and the expected wear thickness W of the grinding stones as known before or in the course of the grinding step (S3) (the absolute value of an expected variation in the thickness of the grinding stones through the grinding step). This can form the recessed portion 15 or 19, in which the angle θ1 or θ2 formed between the bottom surface 15a or 19a and the side surface 15b or 19b is an obtuse angle, in the back surface 11b of the wafer 11 in the above-mentioned grinding method.

It is to be noted that the above-mentioned details relate to an aspect of the present invention, and the present invention is not limited to the above-mentioned details. For example, the present invention may be practiced using a grinding machine provided with a moving mechanism for moving the chuck table 22 along the Z-axis direction and also with another moving mechanism for moving the grinding unit 46 along the X-axis direction. In other words, insofar as the grinding wheel 58 and the wafer 11 can move relative to each other along each of the X-axis direction and the Z-axis direction in the present invention, no limitations are imposed on configurations that realize such relative movements.

If the expected wear thickness of the grinding stones 58a is known, the present invention may be practiced using a grinding machine that does not include the measurement unit 60 having the paired height gauges 60a and 60b. As a further alternative, the present invention may be practiced using a grinding machine that has a contactless measurement unit instead of the measurement unit 60 having the paired height gauges 60a and 60b. In other words, insofar as the depth of the recessed portion formed in the back surface 11b of the wafer 11 can be measured in the present invention, no limitations are imposed on configurations that realize such a measurement.

Moreover, the configurations, the method, and the like according to the above-mentioned embodiment can be practiced with changes or modifications made as appropriate to such extent as not departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding method of a wafer with multiple devices formed on a side of a front surface thereof, for forming a recessed portion of a predetermined depth by grinding the wafer on a side of a back surface thereof, comprising:
a holding step of holding the wafer with the back surface kept exposed,
a contacting step of bringing any one of the multiple grinding stones, the grinding stones being fixed at intervals in an annular pattern on an arrangement surface of a wheel base of a grinding wheel, and a center of the back surface of the wafer into contact with each other while both the grinding wheel and the wafer are being rotated, and
a grinding step of, after the contacting step, grinding the wafer on the side of the back surface thereof by, with both the grinding wheel and the wafer kept rotating, bringing the arrangement surface of the wheel base and the front surface of the wafer closer to each other by a first movement distance along a first direction, and also bringing an axis of rotation of the grinding wheel and a center of the wafer closer to each other by a second movement distance along a second direction perpendicular to the first direction, wherein
the first movement distance is a distance obtained by adding the predetermined depth and an expected wear thickness of the grinding stones when the wafer is ground to the predetermined depth,
the second movement distance is a distance optionally set to be shorter than a width along the second direction of each of the grinding stones,
in the grinding step, the grinding wheel and the wafer are moved relative to each other at a first relative speed along the first direction, and the first relative speed is an optionally set constant speed, and,
in the grinding step, the grinding wheel and the wafer are moved relative to each other at a second relative speed along the second direction, and the second relative speed is a constant or variable speed set, taking the predetermined depth, the expected wear thickness, the second movement distance, and the first relative speed into consideration such that the relative movement of the grinding wheel and the wafer along the first direction and the relative movement of the grinding wheel and the wafer along the second direction are concurrently initiated and are concurrently finished.

2. The grinding method of the wafer according to claim 1, wherein
the expected wear thickness is known before the grinding step, and
the second relative speed is a speed obtained by dividing the second movement distance with a time obtained by dividing the first movement distance with the first relative speed.

3. The grinding method of the wafer according to claim 1, wherein
the recessed portion includes a first portion of an inverted truncated conical shape and a second portion of another inverted truncated conical shape having a side surface with a sharper inclination than a side surface of the first portion,
the grinding step includes
a pre-grinding step of forming the first portion on the side of the back surface of the wafer by, with both the grinding wheel and the wafer kept rotating, bringing the arrangement surface of the wheel base and the front surface of the wafer closer to each other by a third movement distance along the first direction, and also bringing the axis of rotation of the grinding wheel and the center of the wafer closer to each other by a fourth movement distance along the second direction,
a measurement step of, after the pre-grinding step, measuring a depth of the first portion, and
a main grinding step of forming the second portion on the side of the back surface of the wafer by, with both the grinding wheel and the wafer kept rotating, bringing the arrangement surface of the wheel base and the front surface of the wafer closer to each other by a fifth movement distance along the first direction, and also bringing the axis of rotation of the grinding wheel and the center of the wafer closer to each other by a sixth movement distance along the second direction,
the second relative speed in the pre-grinding step is a speed obtained by dividing the second movement distance with a time obtained by dividing the predetermined depth with the first relative speed,
the third movement distance is a distance optionally set to be shorter than the predetermined depth,
the fourth movement distance is a distance obtained by multiplying the second relative speed in the pre-grinding step and a time obtained by dividing the third movement distance with the first relative speed,
the expected wear distance is a distance obtained by multiplying the predetermined depth and a value obtained by dividing, with the depth of the first portion, a distance obtained by subtracting the depth of the first portion from the third movement distance,
the fifth movement distance is a distance obtained by adding a distance, which is obtained by subtracting the third movement distance from the predetermined depth, and the expected wear thickness,
the sixth movement distance is a distance obtained by subtracting the fourth movement distance from the second movement distance, and
the second relative speed in the main grinding step is a speed obtained by dividing the sixth movement distance with a time obtained by dividing the fifth movement distance with the first relative speed.
